(19) United States
(12) Patent Application Publication
(10) Pub. No.: US 2020/0161086 A1
(43) Pub. Date: May 21, 2020

(54) ELECTRON MICROSCOPE EQUIPPED WITH AUTOMATIC BEAM ALIGNMENT

(71) Applicant: EMCRAFTS CO., LTD., Gwangju-si (KR)

(72) Inventor: Jung Bum CHUN, Gwangju-si (KR)

(21) Appl. No.: 16/287,820

(22) Filed: Feb. 27, 2019

(30) Foreign Application Priority Data
Nov. 16, 2018 (KR) 10-2018-0141572

(51) Int. Cl. H01J 37/28; H01J 37/065; H01J 37/147; H01J 37/24

(52) U.S. Cl. CPC H01J 37/28; H01J 37/242; H01J 37/1471; H01J 37/065

(57) ABSTRACT

An electron microscope equipped with automatic beam alignment is provided. The electron microscope can include a vacuum chamber having a receiving space to allow a measurement target specimen to be positioned inside the vacuum chamber. The electron microscope can also include an electron gun coupled to a top of the vacuum chamber with an insulating panel between the electron gun and the vacuum chamber and including a filament module configured to receive power from a power supply and emit an electron beam toward the measurement target specimen. The filament module can be connected to the power supply via a flexible wire inserted into a through hole of the insulating panel such that an assembly error is prevented from occurring when the filament module is coupled to the through hole and the electron beam emitted from the filament module is automatically aligned with a reference optical axis.

### CROSS-REFERENCE TO RELATED APPLICATION

This application claims the benefit of Korean Patent Application No. 10-2018-0141572, filed on Nov. 16, 2018, in the Korean Intellectual Property Office, the disclosure of which is incorporated herein in its entirety by reference.

### BACKGROUND

### 1. Field

One or more embodiments relate to an electron microscope, and more particularly, to an electron microscope equipped with automatic beam alignment, in which a filament tip generating an electron beam is automatically aligned with a reference optical axis when a filament module is replaced.

### 2. Description of the Related Technology

In general, scanning electron microscopes (hereinafter, referred to as “electron microscopes”) obtain information about a specimen that is a target of measurement through a procedure in which the specimen is positioned in a vacuum chamber and an electron beam generated by an electron gun in a tube is scanned across the specimen. In other words, electron microscopes may obtain information about a specimen through a series of a process of detecting an electronic signal generated when an electron beam emitted from a filament collides with the surface of the specimen and a process of displaying the detected electronic signal as an image or recording the detected electronic signal in a recording medium.

In this case, an electron gun is configured to allow current to flow across a filament in a high vacuum chamber and accelerate an electron beam by using a high voltage of about 1 kV to about 30 kV. In such an electron gun, a filament wears down with use and thus needs to be periodically replaced. After replacement, beam alignment for aligning a tip of a filament (hereinafter, referred to as a “filament tip”) generating an electron beam with a reference optical axis needs to be performed.

For reference, the “reference optical axis” refers to an axis which is a sort of reference used to accurately set a spot on a specimen on which an electron beam generated by an electron gun is scanned so that the specimen in a vacuum chamber can be observed under best conditions.

Korea Application Publication 10-2002-0039023 (published on May 25, 2002) discloses beam alignment after replacement of parts of an electron gun.

### SUMMARY

One or more embodiments include an electron microscope equipped with automatic beam alignment, in which a filament tip generating an electron beam is automatically aligned with a reference optical axis without a separate adjustment operation when a filament module is replaced.

Additional aspects will be set forth in part in the description which follows and, in part, will be apparent from the description, or may be learned by practice of the presented embodiments.

According to one or more embodiments, an electron microscope includes a vacuum chamber having a receiving space to allow a measurement target specimen to be positioned inside the vacuum chamber; and an electron gun coupled to a top of the vacuum chamber with an insulating panel between the electron gun and the vacuum chamber and including a filament module configured to receive power from a power supply and emit an electron beam toward the measurement target specimen. The filament module may be connected to the power supply via a flexible wire inserted into a through hole of the insulating panel such that an assembly error is prevented from occurring when the filament module is coupled to the through hole and the electron beam emitted from the filament module is automatically aligned with a reference optical axis.

The flexible wire may be inserted into an electrode housing which has an outer diameter corresponding to an inner diameter of the through hole of the insulating panel and an inner space opening in a side thereof, and a conductive disc may be provided on an opposite side of the inner space of the electrode housing such that an end of the flexible wire connected to the power supply is electrically connected and fixed to the conductive disc.

A socket may be provided at an opposite end of the flexible wire, and an electrode of the filament module may be fitted into and coupled to the socket.

The filament module may include a filament positioned in the vacuum chamber and including a plurality of electrodes such that the filament is connected to the flexible wire in the through hole of the insulating panel; and a Wehnelt assembly fixed surrounding the filament and arranged such that a center of the Wehnelt assembly is aligned with a filament tip in a vertical direction.

The Wehnelt assembly may include a mount coupled to a bottom of the insulating panel and including a seating recess so that the filament is seated in the seating recess, a Wehnelt cap fitted into and coupled to the seating recess of the mount to surround the filament seated in the seating recess, and a fixing nut wrapping around a flange of the Wehnelt cap and screw fastened to an outer circumference of the mount to fix the Wehnelt cap.

The Wehnelt cap may be fitted into the seating recess with no gap between the Wehnelt cap and the seating recess.

The electron microscope may further include a fixing member configured to fix the filament at an aligned position in the Wehnelt cap. The aligned position may be a position of the filament allowing the electron beam to be aligned with the reference optical axis.

The electron microscope may further include a cover positioned on a top of the insulating panel and configured to maintain airtightness by sealing a gap around the through hole in which a wiring line of the power supply is electrically connected to the flexible wire.

The electron microscope may further include a gasket in an interface between the cover and the insulating panel.

According to embodiments, a wiring line of a power supply is connected to an electrode of a filament module using a flexible wire, so that an assembly error may be prevented from occurring when the filament module is replaced and a filament tip generating an electron beam may be automatically aligned with a reference optical axis.

### BRIEF DESCRIPTION OF THE DRAWINGS

These and/or other aspects will become apparent and more readily appreciated from the following description of the embodiments, taken in conjunction with the accompanying drawings.

FIG. 1 is a lateral cross-sectional view of an electron microscope.

FIG. 2 is a detail view of a region A in FIG. 1.

FIG. 3 is a lateral cross-sectional view of an electron microscope equipped with automatic beam alignment, according to an embodiment.

FIG. 4 is partial detail view of a filament module according to an embodiment.

FIG. 5 is an exploded view of the assembly structure of a filament module, according to an embodiment.

FIGS. 6A and 6B are diagrams showing a procedure for aligning the center of a Wehnelt cap with a filament tip, according to an embodiment.

FIG. 7 is a lateral cross-sectional view of the structure of a flexible wire, according to an embodiment.

FIG. 8 is a plan view of a cover provided around through holes of an insulating panel, according to an embodiment.

### DETAILED DESCRIPTION

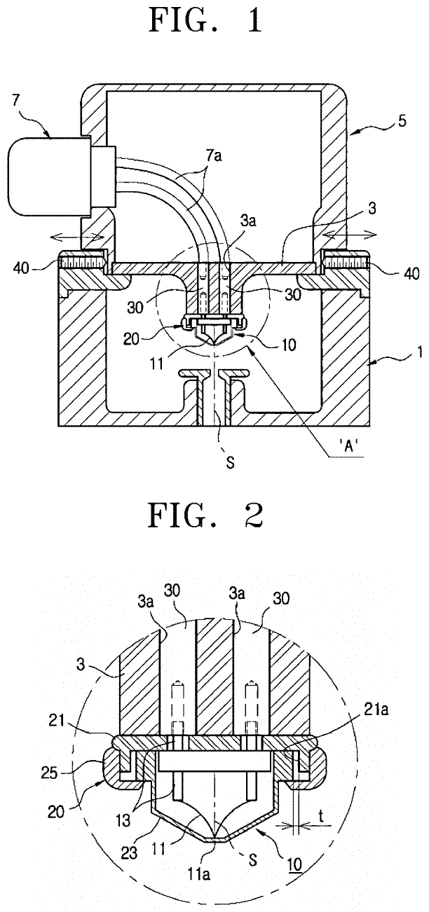

FIG. 1 is a lateral cross-sectional view of an electron microscope. FIG. 2 is a detail view of a region A in FIG. 1.

Referring to FIGS. 1 and 2, the electron microscope includes a vacuum chamber 1, in which a measurement target specimen is positioned, and an electron gun 5, which is coupled to a top of the vacuum chamber 1 with an insulating panel 3 between the electron gun 5 and the vacuum chamber 1 and emits an electron beam toward the measurement target specimen. A filament module 10 generating an electron beam is provided in the electron gun 5. In this case, the filament module 10 includes a filament 11 and a Wehnelt assembly 20. The filament 11 is made of tungsten and includes an electrode 13. The Wehnelt assembly 20 surrounds the filament 11 to prevent electric discharge from occurring due to high voltage in vacuum.

Referring to FIG. 2, the Wehnelt assembly 20 may include a mount 21, a Wehnelt cap 23, and a fixing nut 25. The mount 21 is coupled to a bottom of the insulating panel 3. The Wehnelt cap 23 is seated in a seating recess 21a to surround the filament 11. The fixing nut 25 fixes the Wehnelt cap 23 to the mount 21.

In addition, a feedthrough pin 30 is provided in a through hole 3a of the insulating panel 3 on which the filament module 10 is mounted. The feedthrough pin 30 maintains airtightness so that a wiring line 7a of a power supply 7 supplying power to the electron gun 5 is connected to the filament module 10 in the vacuum chamber 1.

In other words, since the wiring line 7a (see FIG. 1) is positioned in a main body of the electron gun 5 in the atmospheric pressure and the filament module 10 is positioned in the vacuum chamber 1 in a vacuum state, the feedthrough pin 30 is provided in the through hole 3a of the insulating panel 3 that is a border at which the wiring line 7a is connected to the filament module 10. Accordingly, the airtightness between atmospheric pressure and the vacuum may be easily maintained.

At the time of replacement and coupling of the filament module 10 having such structure, the center of the Wehnelt cap 23 needs to be aligned with a filament tip 11a so that the filament module 10 may generate electron beams having uniform density in all directions around a reference optical axis S. Since the filament tip 11a of the electron gun 5 is a substantial source of electron beams, an adjustment operation for aligning the filament tip 11a with the reference optical axis S is needed. In other words, the filament 11 is made by welding a bent tungsten wire to the electrode 13 and welding may not be performed in the same shape all the time. Accordingly, when the filament module 10 is replaced, an adjustment operation for aligning the filament tip 11a with the reference optical axis S is needed.

In particular, the feedthrough pin 30 of the electron gun 5 is made as a fixed type. Accordingly, when the electrode 13 of the filament 11 is inserted into and coupled to a lower portion of the feedthrough pin 30 without alignment of the filament tip 11a, an assembly error occurs between the filament tip 11a and the reference optical axis S.

Taking such assembly error into consideration, a certain marginal gap “t” is provided in the seating recess 21a of the mount 21, in which the Wehnelt cap 23 is seated such that the filament module 10 can be mounted. In addition, an adjustment operation is performed using a plurality of adjustment bolts 40 provided at an outer circumference of the main body of the electron gun 5 such that the filament tip 11a of the filament module 10 is aligned with the reference optical axis S after the filament module 10 is mounted.

However, the adjustment operation using the adjustment bolts 40 needs to be performed by a user of the electron microscope each time the filament module 10 is replaced, causing the user an inconvenience.

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

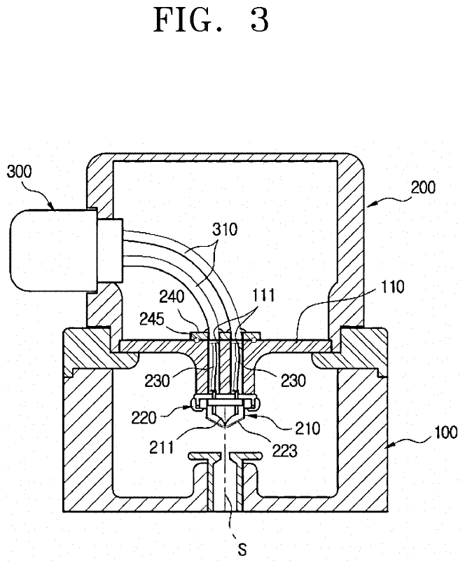

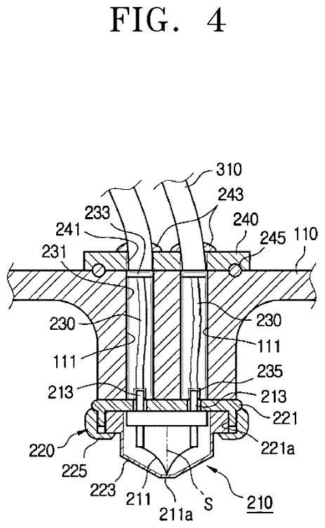

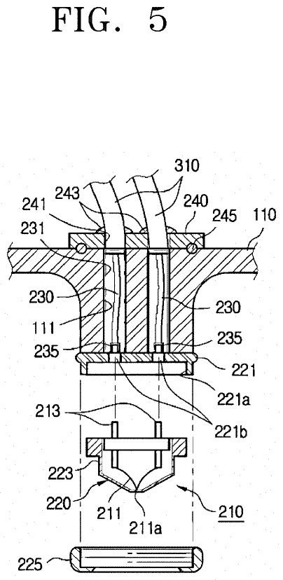

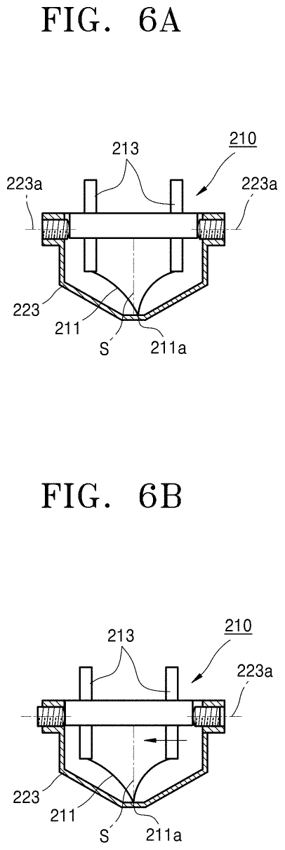

FIG. 3 is a lateral cross-sectional view of an electron microscope equipped with automatic beam alignment, according to an embodiment. FIG. 4 is partial detail view of a filament module according to an embodiment. FIG. 5 is an exploded view of the assembly structure of a filament module, according to an embodiment. FIGS. 6A and 6B are diagrams showing a procedure for aligning the center of a Wehnelt cap with a filament tip, according to an embodiment.

Referring to FIG. 3, the electron microscope equipped with automatic beam alignment includes a vacuum chamber 100 and an electron gun 200. The electron gun 200 includes a filament module 210 generating an electron beam. The configuration of the electron microscope will be described in detail below.

The vacuum chamber 100 has a receiving space therein to allow a measurement target specimen (not shown) to be positioned inside the vacuum chamber 100. The vacuum chamber 100 may include a door (not shown) on at least one side thereof such that the measurement target specimen may be put in the receiving space through the door. Since the vacuum chamber 100 has a usual structure applied to electron microscopes such as in FIGS. 1 and 2, detailed descriptions of the vacuum chamber 100 will be omitted.

The electron gun 200 receives power from a power supply 300 and emits an electron beam toward a measurement target specimen in the vacuum chamber 100. The electron gun 200 includes the filament module 210 generating an electron beam. In this case, the electron gun 200 is coupled to a top of the vacuum chamber 100 with an insulating panel 110 between the electron gun 200 and the vacuum chamber 100. The filament module 210 is positioned in the receiving space of the vacuum chamber 100.

Referring to FIG. 4, the filament module 210 is connected to a wiring line 310 of the power supply 300 via a flexible wire 230 inserted into a through hole 111 of the insulating panel 110 such that an assembly error is prevented from occurring when the filament module 210 is coupled to the through hole 111. Accordingly, an electron generated from the filament module 210 may be automatically aligned with a reference optical axis S.

The filament module 210 includes a filament 211 and a Wehnelt assembly 220. The filament 211 includes a plurality of electrodes 213 such that the filament 211 may be connected to the flexible wire 230 provided in the through hole 111 of the insulating panel 110. The Wehnelt assembly 220 is fixed surrounding the filament 211 and is arranged such that the center of the Wehnelt assembly 220 is aligned with a filament tip 211a in a vertical direction.

Referring to FIG. 5, the Wehnelt assembly 220 may include a mount 221, a Wehnelt cap 223, and a fixing nut 225. The mount 221 is coupled to a bottom of the insulating panel 110 and includes a seating recess 221a so that the filament 211 including the electrodes 213 is seated in the seating recess 221a. The Wehnelt cap 223 is fitted into and coupled to the seating recess 221a of the mount 221 to surround the filament 211. The fixing nut 225 wraps around a flange of the Wehnelt cap 223 and is screw fastened to an outer circumference of the mount 221, thereby fixing the Wehnelt cap 223.

Referring to FIGS. 6A and 6B, the filament 211 in the Wehnelt cap 223 may be moved for alignment and then fixed at an aligned position using a fixing member 223a such as a bolt. In other words, the filament tip 211a of the filament module 210 may be displaced from the center of the Wehnelt cap 223 (see FIG. 6A). In this case, the filament tip 211a may be aligned with the center of the Wehnelt cap 223 by adjusting the position of the filament 211 using the fixing member 223a (see FIG. 6B).

Referring back to FIG. 5, the Wehnelt cap 223 may be fitted into and coupled to the seating recess 221a with no gap between the Wehnelt cap 223 and the seating recess 221a. The Wehnelt cap 223 may maintain an accurate assembly position without a movement in the seating recess 221a. In other words, the filament module 210 may be already in a state where an electron beam is aligned with the reference optical axis S and may be accurately arranged at a preset assembly position at the time of replacement. Accordingly, an electron beam may be aligned with the reference optical axis S at the time of replacement only by combining the filament module 210 with the electron gun 200 without a separate adjustment operation after the replacement.

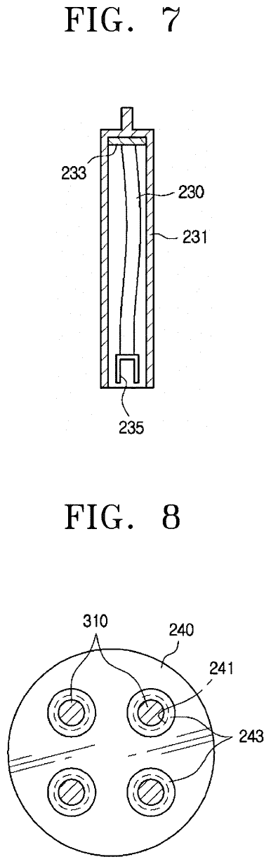

FIG. 7 is a lateral cross-sectional view of the structure of the flexible wire 230, according to an embodiment. Referring to FIG. 7, the flexible wire 230 is provided in an electrode housing 231 combined with the through hole 111.

In detail, the electrode housing 231 has an outer diameter, which corresponds to an inner diameter of the through hole 111 of the insulating panel 110, and an inner space opening in a side thereof. A conductive disc 233 may be provided on an opposite side of the inner space of the electrode housing 231 such that an end of the flexible wire 230 connected to the wiring line 310 of the power supply 300 may be fixed to the conductive disc 233 via soldering or the like.

A socket 235 may be provided at an opposite end of the flexible wire 230. The electrode 213 of the filament 211 is fitted into and coupled to the socket 235. An outer diameter of the socket 235 may be less than an inner diameter of the electrode housing 231 such that the socket 235 may move in all directions in the electrode housing 231.

The flexible wire 230 is not rigid but is flexible to be movable, and accordingly, an assembly error is prevented from occurring when the filament module 210 is fitted into and coupled to the flexible wire 230. In other words, when the Wehnelt cap 223 in which the position of the filament tip 211a is adjusted (see FIGS. 6A and 6B) is coupled to the seating recess 221a of the mount 221, an assembly position of the electrode 213 of the filament 211 may be changed, wherein the electrode 213 is connected to the flexible wire 230 through a fitting hole 221b of the mount 221. At this time, since the flexible wire 230 is movable, an assembly error of the filament 211 may be automatically corrected.

Meanwhile, a cover 240 (see FIG. 5) may be provided on a top of the insulating panel 110. The cover 240 blocks a gap around the through hole 111 through which the wiring line 310 of the power supply 300 is connected to the flexible wire 230, thereby maintaining airtightness. The cover 240 may include a synthetic resin or a printed circuit board (PCB) substrate.

FIG. 8 is a plan view of the cover 240 provided around the through hole 111 of the insulating panel 110, according to an embodiment. Referring to FIG. 8, insertion holes 241 are formed in the cover 240 such that a plurality of wiring lines 310 may be respectively fitted into and coupled to the insertion holes 241. A gap between each of the wiring lines 310 and a corresponding one of the insertion holes 241 may be sealed by a solder portion 243 so that airtightness may be maintained. In addition, a gasket 245 (see FIG. 5) may be provided in an interface between the cover 240 and the insulating panel 110.

As described above, according to an electron microscope equipped with automatic beam alignment, the wiring line 310 of the power supply 300 is connected to the electrode 213 of the filament module 210 via the flexible wire 230, so that an assembly error may be prevented from occurring when the filament module 210 is replaced. In addition, the filament 211 may be aligned with the reference optical axis S in the filament module 210 before the filament module 210 is assembled with the electron microscope. Accordingly, the filament tip 211a generating an electron beam may be automatically aligned with the reference optical axis S without performing a separate adjustment operation after the filament module 210 is mounted on the insulating panel 110.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the disclosure as defined by the following claims.

What is claimed is:

1. An electron microscope comprising:
a vacuum chamber having a receiving space to allow a measurement target specimen to be positioned inside the vacuum chamber; and
an electron gun coupled to a top of the vacuum chamber with an insulating panel between the electron gun and the vacuum chamber and including a filament module configured to receive power from a power supply and emit an electron beam toward the measurement target specimen,
wherein the filament module is connected to the power supply via a flexible wire inserted into a through hole of the insulating panel such that an assembly error is prevented from occurring when the filament module is coupled to the through hole and the electron beam emitted from the filament module is automatically aligned with a reference optical axis.

2. The electron microscope of claim 1, wherein the flexible wire is inserted into an electrode housing which has an outer diameter corresponding to an inner diameter of the through hole of the insulating panel and an inner space opening in a side thereof, and
wherein a conductive disc is provided on an opposite side of the inner space of the electrode housing such that an end of the flexible wire connected to the power supply is electrically connected and fixed to the conductive disc.

3. The electron microscope of claim 2, further comprising a socket provided at an opposite end of the flexible wire, wherein an electrode of the filament module is fitted into and coupled to the socket.

4. The electron microscope of claim 1, wherein the filament module comprises:
a filament positioned in the vacuum chamber and including a plurality of electrodes such that the filament is connected to the flexible wire in the through hole of the insulating panel; and
a Wehnelt assembly fixed surrounding the filament and arranged such that a center of the Wehnelt assembly is aligned with a filament tip in a vertical direction.

5. The electron microscope of claim 4, wherein the Wehnelt assembly comprises:
a mount coupled to a bottom of the insulating panel and including a seating recess so that the filament is seated in the seating recess;
a Wehnelt cap fitted into and coupled to the seating recess of the mount to surround the filament seated in the seating recess; and
a fixing nut wrapping around a flange of the Wehnelt cap and screw fastened to an outer circumference of the mount to fix the Wehnelt cap.

6. The electron microscope of claim 5, wherein the Wehnelt cap is fitted into the seating recess with no gap between the Wehnelt cap and the seating recess.

7. The electron microscope of claim 5, further comprising a fixing member configured to fix the filament at an aligned position in the Wehnelt cap.

8. The electron microscope of claim 7, wherein the aligned position is a position of the filament allowing the electron beam to be aligned with the reference optical axis.

9. The electron microscope of claim 1, further comprising a cover positioned on a top of the insulating panel and configured to maintain airtightness by sealing a gap around the through hole in which a wiring line of the power supply is electrically connected to the flexible wire.

10. The electron microscope of claim 9, further comprising a gasket in an interface between the cover and the insulating panel.
